(19) United States
(12) Patent Application Publication
(10) Pub. No.: US 2016/0043108 A1
(43) Pub. Date: Feb. 11, 2016

(54) Semiconductor Structure with Multiple Active Layers in an SOI Wafer

(71) Applicant: Silanna Semiconductor U.S.A., Inc., San Diego, CA (US)

(72) Inventor: Stephen A. Fanelli, San Marcos, CA (US)

(21) Appl. No.: 14/454,262

(22) Filed: Aug. 7, 2014

(51) Int. Cl. H01L 27/12; H01L 21/84; B81C 3/00; B81B 7/00; B81B 7/02; H01L 21/762; B81C 1/00

(52) U.S. Cl. CPC H01L 27/1207; H01L 21/76251; H01L 21/84; B81C 1/00523; B81B 7/0019; B81B 7/0006; B81B 7/02; B81B 7/0074; B81C 3/001; B81C 2203/0714; B81C 2203/0728

(57) ABSTRACT

An semiconductor on insulator wafer has an insulator layer between a substrate layer and a semiconductor layer. A first active layer is formed in and on the semiconductor layer. A second active layer is formed in and on the substrate layer. In some embodiments, a handle wafer is bonded to the semiconductor on insulator wafer, and the substrate layer is thinned before forming the second active layer. In some embodiments, a third active layer may be formed in the substrate of the handle wafer. In some embodiments, the first and second active layers include a MEMS device in one of these layers and a CMOS device in the other.

### BACKGROUND OF THE INVENTION

Integrated circuits (ICs) vertical integration techniques utilize multiple active/device layers on a single die. These techniques allows for a significant increase in the number of components per IC without increasing the required die area. The die thickness may be increased, but it is the die area that is usually more of a limiting design consideration, and the overall result can be a reduced total die volume and IC package weight. The development of vertical integration techniques is, thus, of paramount importance for technologies in which electronic devices must be relatively small and lightweight, e.g. cell/smart phones, notebook/tablet PCs, etc.

### SUMMARY

Embodiments of the present invention involve a semiconductor structure with multiple active layers formed from an SOI wafer. The typical SOI wafer has an insulator layer (e.g. a buried oxide) between a substrate layer and a semiconductor layer. A first active layer is formed in and on the semiconductor layer. A second active layer is formed in and on the substrate layer. In some embodiments, a handle wafer is bonded to the SOI wafer, and the substrate layer is thinned before forming the second active layer. In some embodiments, a third active layer may be formed in the substrate of the handle wafer. In some embodiments, the first and second active layers include a MEMS device in one of these layers and a CMOS device in the other.

A more complete appreciation of the present disclosure and its scope, and the manner in which it achieves the above noted improvements, can be obtained by reference to the following detailed description of presently preferred embodiments taken in connection with the accompanying drawings, which are briefly summarized below, and the appended claims.

### BRIEF DESCRIPTION OF THE DRAWINGS

FIG. 1 is a simplified cross-section of a semiconductor structure incorporating an embodiment of the present invention.

FIGS. 2-5 are simplified cross-sections of semiconductor structures at intermediate stages in the fabrication of the semiconductor structure shown in FIG. 1 in accordance with embodiments of the present invention.

FIG. 6 is a simplified cross-section of an alternative semiconductor structure incorporating an embodiment of the present invention.

### DETAILED DESCRIPTION OF THE INVENTION

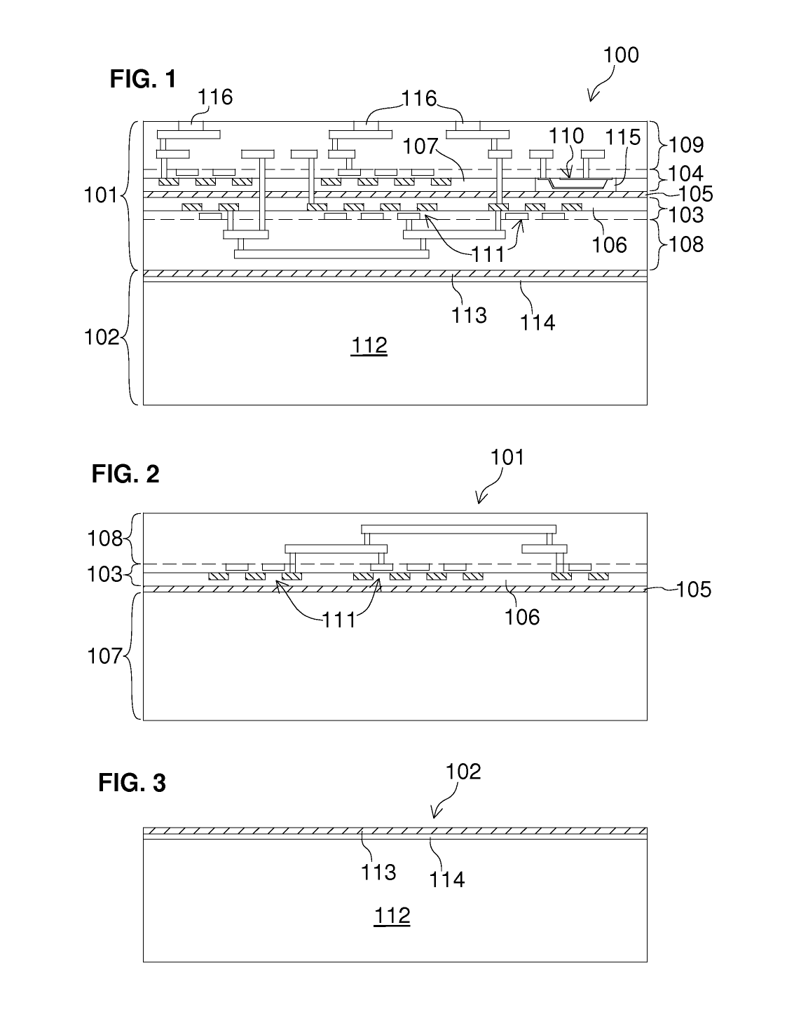

According to some embodiments, the present invention achieves vertical integration of active layers in a monolithically formed IC semiconductor structure (e.g. semiconductor structure 100 of FIG. 1) using a semiconductor-on-insulator (SOI) wafer. In general, after a first active layer is formed in and on the SOI wafer, the SOI wafer is inverted, and a second active layer is formed in and on the underlying substrate, as described in more detail below. This technique generally enables a relatively compact vertical integration of a variety of types of active layers with a significant reduction of die area and an increase in die per wafer. Additionally, in some embodiments, the multiple active layers may enable the integration of CMOS devices in the same monolithic semiconductor structure with other types of devices, such as film bulk acoustic resonators, surface acoustic wave devices, film plate acoustic resonators (FPAR), acoustic filters, RF switches, passive components, and other microelectromechanical systems (MEMS) devices.

In the example shown in FIG. 1, the semiconductor structure 100 generally has an inverted SOI wafer 101 bonded with a handle wafer 102. The SOI wafer 101 generally has two active layers 103 and 104 on both opposite sides (i.e. top/bottom or upper/lower) of an insulator layer 105 (e.g. a buried oxide). The first active layer 103 is formed in and on the conventional semiconductor layer 106 of the SOI wafer 101. The second active layer 104 is formed in and on the underlying conventional substrate layer 107 of the SOI wafer 101, or the portion that remains after thinning the original substrate layer 107. The components that are shown within the active layers 103 and 104 are provided for illustrative purposes only and do not necessarily depict limitations on the present invention.

Additionally, the SOI wafer 101 generally includes interconnect layers 108 and 109, through which electrical connections may be made between the various components of the active layers 103 and 104. The components that are shown within the interconnect layers 108 and 109 are provided for illustrative purposes only and do not necessarily depict limitations on the present invention. In some embodiments, for example, one of the active layers (e.g. 104) may include an RF/MEMS device 110 (among other components), and the other active layer (e.g. 103) may include CMOS devices 111 (among other components) for circuitry that controls operation of the MEMS device 110.

The handle wafer 102 generally includes a handle substrate layer 112, a bonding layer 113, and an optional trap rich layer (TRL) 114. The handle wafer 102 is bonded to a top surface of the SOI wafer 101 (inverted as shown) after the formation of the first active layer 103 and the first interconnect layer 108. The handle wafer 102 is generally used to provide structural stability for the semiconductor structure 100 while processing the substrate layer 107 of the SOI wafer 101 and the formation of the second active layer 104 and second interconnect layer 109. In some embodiments, the structural stability aspect enables the substrate layer 107 of the SOI wafer 101 to be thinned before formation of the second active layer 104.

The first and second active layers 103 and 104 and the first and second interconnect layers 108 and 109 are described herein as being built up both into and onto the semiconductor layer 106 and substrate layer 107, respectively. This type of fabrication technique is known as a “monolithic” style of fabrication. A different technique of active layer fabrication is known as a “layer transfer” style, which involves the formation of the active layers in and on multiple separate wafers, followed by transferring one of the active layers onto the wafer of the other. There are various advantages and disadvantages for both of these techniques. The monolithic style, for example, generally requires serial processing for each of the manufacturing steps; whereas, the layer transfer style allows for parallel processing of the multiple wafers, thereby potentially reducing the overall time to manufacture the final semiconductor structure. However, the monolithic style generally does not require the expense of multiple substrates, does not require wafer bonding or wafer cleavage steps, does not require significant grinding or etching back steps, does not require precision wafer-aligning for bonding, and does not require a capital investment for fabrication machines that can perform the wafer-bonding-related steps. Some general exceptions to these advantages may occur in some situations, such as the wafer bonding of the handle wafer 102. However, since the handle wafer 102 does not have additional circuitry prior to bonding, there is no need for a high-precision alignment of the wafers 101 and 102. Thus, the bonding step for the handle wafer 102 can be relatively simple and cheap compared to approaches where multiple active layers on multiple wafers are integrated via a layer transfer process.

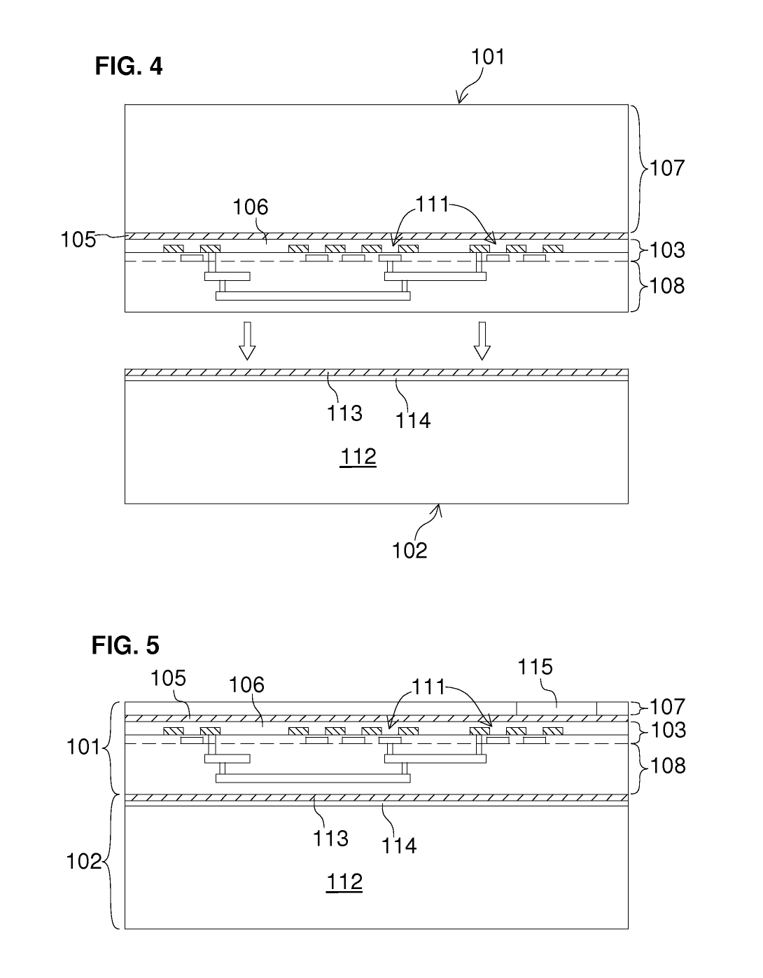

A simplified example manufacturing process, according to some embodiments for forming the semiconductor structure 100 of FIG. 1, is shown by FIGS. 2-5. The process generally starts with the SOI wafer 101 having the insulator layer 105 (e.g. a buried oxide) between the semiconductor layer 106 and substrate layer 107 as shown in FIG. 2. The first active layer 103 is then formed into and onto the “top” or “upper” surface of the semiconductor layer 106 using mostly conventional process steps. In situations where the active devices in active layer 103 are CMOS transistors, these process steps are those typically associated with single wafer monolithic CMOS manufacturing. Additionally, instead of or in addition to the TRL 114 in the handle wafer 102, the SOI wafer 101 may include a TRL formed as disclosed in U.S. patent application Ser. No. 14/454,370, filed Aug. 7, 2014, the disclosure of which is incorporated by reference herein in its entirety.

The first interconnect layer 108 is then formed on the “top” or “upper” surface of the first active layer 103. Since the SOI wafer 101 is subsequently inverted from the orientation shown in FIG. 2, for the benefit of consistency in description, the portion of the SOI wafer 101 referred to as the “top” (or “upper” or “front”) with respect to FIG. 2 will continue to be referred to herein as the “top” (or “upper” or “front”), and the portion of the SOI wafer 101 referred to as the “bottom” (or “lower” or “back”) will continue to be referred to herein as the “bottom” (or “lower” or “back”), even after the SOI wafer 101 has been inverted. Therefore, in FIG. 1, the “top” of the overall semiconductor structure 100 is considered the same as the “bottom” of the SOI wafer 101. Also, when the top of the overall semiconductor structure 100 is being processed, it is considered “back side” processing for the SOI wafer 101.

Additionally, for purposes of description herein, when material or layers are added to a wafer, the added material or layers are considered to become part of the wafer. Also, when material or layers are removed from the wafer, the removed material or layers are no longer considered to be part of the wafer. Therefore, for example, the element designated as the SOI wafer 101 or the handle wafer 102 in the Figs. may increase or decrease in size or thickness as it is being processed.

Also, for purposes of description herein, a surface referred to as the “top surface” or “bottom surface” of a wafer may change during processing when material or layers are added to or removed from the wafer. For example, the first active layer 103 is formed by front side processing in and on the top surface of the SOI wafer 101, but the material that is placed on the SOI wafer 101 creates a new top surface. Thus, the first interconnect layer 108 is formed on the new top surface. Then when the handle wafer 102 is bonded to the SOI wafer 101, it is bonded to yet another new top surface thereof.

Furthermore, various layers of materials are described herein. However, there is not necessarily a distinct demarcation line between some of the layers. For example, some materials formed during fabrication of the interconnect layers 108 or 109 may extend into other layers. Through semiconductor vias (TSVs), for example, may be formed through the active layers 103 or 104 and the insulator layer 105. Other examples of overlapping layers may also become apparent.

The simplified example manufacturing process, according to some embodiments for forming the semiconductor structure 100 of FIG. 1, continues with the formation of the handle wafer 102 as shown in FIG. 3. The bonding layer 113, and the TRL 114 are formed on the handle substrate layer 112. The handle substrate layer 112 is generally thick enough to provide structural stability or strength to the semiconductor structure 100. The TRL 114 is formed by any appropriate technique, e.g. implanting ions of high energy particles (e.g. a noble gas, Silicon, Oxygen, Carbon, Germanium, etc.), irradiating the handle wafer 102, depositing high resistivity material, damaging the exposed surfaces of the handle substrate layer 112, etc. In some embodiments, the TRL 114 is formed as disclosed in U.S. patent application Ser. No. 14/454,370, filed Aug. 7, 2014, the disclosure of which is incorporated by reference herein in its entirety. The bonding layer 113 may be any appropriate material that can be bonded to the material at the top surface of the SOI wafer 101. Other bonding techniques for other embodiments with or without the bonding layer 113 may also be used. In some embodiments, the bonding layer 113 may be combined with the TRL 114. In some embodiments, the entire handle wafer 102 will be the TRL 114.

As shown in FIG. 4, SOI wafer 101 of FIG. 2 is bonded to the handle wafer 102 of FIG. 3. The SOI wafer 101 is inverted in FIG. 4 relative to its orientation in FIG. 2. The surface of the SOI wafer 101 to which the handle wafer 102 is bonded is the top surface, which is opposite the insulator layer from the substrate layer 107. This step leaves the bottom or back side of the SOI wafer 101 exposed for processing. The handle wafer 102 provides structural stability during this processing.

A portion of the substrate layer 107 is removed, thereby thinning the substrate layer 107, as shown in FIG. 5. The remaining portion of the substrate layer 107 is sufficiently thick to be used as a new semiconductor layer for the formation of a second active layer, such as the second active layer 104 in FIG. 1.

In some embodiments, since the MEMS device 110 is to be formed in the second active layer 104, a cavity 115 may be formed in the substrate layer 107. The cavity 115 at least partly surrounds the MEMS device 110. The cavity 115 may be formed by any appropriate technique, e.g. orientation dependent etch, anisotropic etch, isotropic etch, etc. The cavity 115 provides isolation, improved thermal performance and/or a material for release of the MEMS device 110. A fill material is then placed inside the cavity 115 and planarized, e.g. by CMP. The fill material may be selective to the material that forms second active layer 104, so the fill material can be removed later to release the MEMS device 110. In some embodiments, the cavity 115 may extend into the insulator layer 105, so the fill material may have to be selective to the insulator material.

The second active layer 104 is then formed in and on the remaining portion of the substrate layer 107. In some embodiments, fabrication of the MEMS device 110 within the second active layer 104 is done in reverse order from the conventional process. This reverse process may aid in simplifying the bonding and interconnection for low temperatures (e.g. less than 200° C.).

The second interconnect layer 109 is then formed on the second active layer 104 (and through the two active layers 103 and 104) to produce the semiconductor structure 100 shown in FIG. 1. In some embodiments, some of the electrical connections between the two active layers 103 and 104 may be formed with a buried contact, e.g. forming TSVs early in the overall fabrication process. Electrical connection pads 116 and a redistribution layer (not shown) may also be formed for external electrical connections. Electrical interconnects, e.g. TSVs, that pass through more than one layer may provide electrical connections between any two or more components in the two interconnect layers 108 and 109 and the active layers 103 and 104, e.g. a TSV interconnect between metallization in the interconnect layers 108 and 109, or a TSV interconnect between metallization in one of the interconnect layers 108 or 109 and an active device (e.g. source, drain or gate region) in one of the active layers 108 or 109.

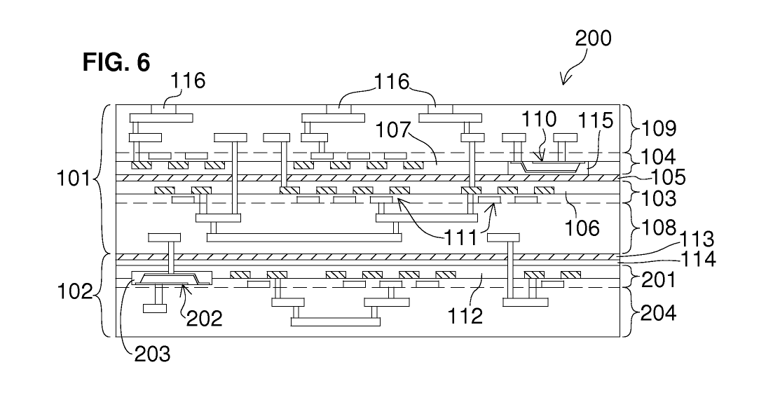

An alternative semiconductor structure 200 incorporating an alternative embodiment of the present invention is shown in FIG. 6. In this case, many of the elements are similar to those of the embodiment shown in FIG. 1, because this embodiment may be built up from the semiconductor structure 100. However, a portion of the handle substrate layer 112 is removed, thereby thinning the handle substrate layer 112. The remaining portion of the handle substrate layer 112 is sufficiently thick to be used as a new semiconductor layer for the formation of a third active layer 201, thereby monolithically forming yet another active layer. In some embodiments, another handle wafer (not shown) may be bonded to the semiconductor structure 100 to provide structural stability during subsequent processing if the existing thickness of the semiconductor structure 100 does not provide sufficient structural stability.

In some embodiments, a MEMS device 202 is formed in the third active layer 201, such that a cavity 203 may need to be formed in the handle substrate layer 112. The cavity 203 may be formed by any appropriate technique, e.g. orientation dependent etch, anisotropic etch, isotropic etch, etc. The cavity 203 provides isolation, improved thermal performance and/or a material for release of the MEMS device 202. A fill material is then placed inside the cavity 203 and planarized, e.g. by CMP. The fill material may be selective to the material of third active layer 201, so the fill material can be removed later to release the MEMS device 202.

The third active layer 201 is then formed in and on the remaining portion of the handle substrate layer 112.

A third interconnect layer 204 is then formed on the third active layer 201 (and through to the first active layer 103) to produce the semiconductor structure 200 shown in FIG. 6. In some embodiments, some of the electrical connections between the first and third active layers 103 and 201 may be formed with a buried contact, e.g. forming TSVs early in the overall fabrication process. The third active layer 201 may also be connected to the second active layer 104 via contacts between those layers and a common circuit node in interconnect layer 108. Electrical connection pads (not shown) and a redistribution layer (not shown) may also be formed for external electrical connections on the bottom side of the alternative semiconductor structure 200. Alternatively or in combination, electrical connection pads 116 and a redistribution layer (not shown) may also be formed for external electrical connections to the bottom side of the alternative semiconductor structure 200.

Although embodiments of the present invention have been discussed primarily with respect to specific embodiments thereof, other variations are possible. Various configurations of the described system may be used in place of, or in addition to, the configurations presented herein. For example, additional components may be included where appropriate. As another example, configurations were described with general reference to certain types and combinations of semiconductor components, but other types and/or combinations of semiconductor components could be used in addition to or in the place of those described.

Those skilled in the art will appreciate that the foregoing description is by way of example only, and is not intended to limit the present invention. Nothing in the disclosure should indicate that the present invention is limited to systems that have the specific type of semiconductor components shown and described, unless otherwise indicated in the claims. Nothing in the disclosure should indicate that the present invention is limited to systems that require a particular form of semiconductor processing or integrated circuits, unless otherwise indicated in the claims. In general, any diagrams presented are only intended to indicate one possible configuration, and many variations are possible. Those skilled in the art will also appreciate that methods and systems consistent with the present invention are suitable for use in a wide range of applications.

While the specification has been described in detail with respect to specific embodiments of the present invention, it will be appreciated that those skilled in the art, upon attaining an understanding of the foregoing, may readily conceive of alterations to, variations of, and equivalents to these embodiments. These and other modifications and variations to the present invention may be practiced by those skilled in the art, without departing from the spirit and scope of the present invention, which is more particularly set forth in the appended claims.

1. A method comprising:
providing a semiconductor on insulator (SOI) wafer having an insulator layer between a substrate layer and a semiconductor layer;
forming a first active layer in and on the semiconductor layer of the SOI wafer; and
forming a second active layer in and on the substrate layer of the same SOI wafer.

2. The method of claim 1, further comprising:
removing a first portion of the substrate layer; and
forming the second active layer in and on a second portion of the substrate layer.

3. The method of claim 2, further comprising:
before the removing of the first portion of the substrate layer, bonding a handle wafer to a first surface of the semiconductor on insulator wafer; and
removing the first portion of the substrate layer from a second surface of the semiconductor on insulator wafer.

4. The method of claim 3, further comprising:
providing a trap rich layer in the handle wafer.

5. The method of claim 1, further comprising:
bonding a handle wafer to a surface of the semiconductor on insulator wafer, the surface of the semiconductor on insulator wafer being opposite the insulator layer from the substrate layer, and the handle wafer having a handle substrate layer; and
forming a third active layer in and on the handle substrate layer.

6. The method of claim 5, further comprising:
removing a first portion of the handle substrate layer; and
forming the third active layer in and on a second portion of the handle substrate layer.

7. The method of claim 1, further comprising:
forming an interconnect layer on the second active layer; and
forming electrical connections between the interconnect layer and the first and second active layers.

8. The method of claim 1, further comprising:
forming a MEMS device in and on the substrate layer.

9. The method of claim 8, further comprising:
forming a cavity for the MEMS device in at least one of: the substrate layer and the insulator layer.

10. The method of claim 8, wherein:
the forming of the first active layer further comprises forming a CMOS device; and
the method further comprises forming an electrical connection between the CMOS device and the MEMS device, the CMOS device providing a control signal for the MEMS device through the electrical connection.

11. A semiconductor structure comprising:
a semiconductor on insulator (SOI) wafer having an insulator layer between a semiconductor layer and a substrate layer;
a first active layer formed in and on the semiconductor layer of the SOI wafer; and
a second active layer formed in and on the substrate layer of the same SOI wafer.

12. The semiconductor structure of claim 11, wherein:
the second active layer is formed in and on a remaining portion of the substrate layer after the substrate layer has been thinned.

13. The semiconductor structure of claim 12, further comprising:
a handle wafer bonded to a surface of the semiconductor on insulator wafer opposite the insulator layer from the substrate layer.

14. The semiconductor structure of claim 13, wherein:
the handle wafer has a trap rich layer.

15. The semiconductor structure of claim 11, further comprising:
a handle wafer bonded to a surface of the semiconductor on insulator wafer, the surface of the semiconductor on insulator wafer being opposite the insulator layer from the substrate layer, the handle wafer having a handle substrate layer; and
a third active layer formed in and on the handle substrate layer.

16. The semiconductor structure of claim 15, wherein:
the third active layer is formed in and on a remaining portion of the handle substrate layer after the handle substrate layer has been thinned.

17. The semiconductor structure of claim 11, further comprising:
an interconnect layer formed on the second active layer; and
electrical connections between the interconnect layer and the first and second active layers.

18. The semiconductor structure of claim 11, further comprising:
a MEMS device formed in and on the substrate layer.

19. The semiconductor structure of claim 18, further comprising:
a cavity surrounding at least part of the MEMS device, the cavity being formed in at least one of: the substrate layer and the insulator layer.

20. The semiconductor structure of claim 18, wherein:
the first active layer includes a CMOS device; and
the CMOS device provides a control signal for the MEMS device.
